(19) United States
(12) Patent Application Publication
(10) Pub. No.: US 2003/0039754 A1
(43) Pub. Date: Feb. 27, 2003

(54) Preactivation of plastic surfaces to be metallized

(75) Inventor: Andreas Johannes Konigshofen, Koln (DE)

Correspondence Address: SENNIGER POWERS LEAVITT AND ROEDEL, ONE METROPOLITAN SQUARE, 16TH FLOOR, ST LOUIS, MO, 63102, US

(73) Assignee: Enthone Inc

(21) Appl. No.: 10/212,411

(22) Filed: Aug. 5, 2002

(30) Foreign Application Priority Data
Aug. 4, 2001 (DE) 101 38 446.7

(51) Int. Cl. B05D 3/10; C23C 16/02

(52) U.S. Cl. 427/304; 106/1.11

(57) ABSTRACT

A plastic surface to be metallized is contacted with a preactivation solution after an etching step and before an activation step. The solution comprises permanganate, a crosslinking agent, and a pH buffer material. As a result of the preactivation treatment with the solution, the plastic surface is changed in such a manner that the activation step can be carried out more efficiently. The method enables plastics to be metallized more efficiently and at lower cost, or in some cases to be metallized at all.

### BACKGROUND OF THE INVENTION

The invention relates to the metallization of a plastic surface, where the plastic surface is etched, activated and then galvanized.

Methods for the direct metallization of plastic surfaces are known in the state of the art. Their purpose is to confer particular properties to a given plastic. Plastics are galvanized in particular to produce a decorative appearance.

In the known methods, the plastic surface is first etched in order to roughen it or chemically modify it. This treatment can be carried out, for example, with chromic acid, chromosulfuric acid or acidic or alkaline permanganese etching agents or by means of plasma treatment. Other oxidizing etching agents are also known in the state of the art. As a result of the etching process, the plastic surface is roughened or chemically modified in such a manner that adhesion between plastic and metal coating becomes possible. The etched plastic parts are rinsed and then activated. Different methods for activating the plastic surface are known in the state of the art. Thus, it is known to activate the plastic surface with noble metals such as, for example, colloidal palladium, ionogenic palladium or silver colloids. It is also known to use metals as activators, which form sulfides and polysulfides with low solubility. In particular, tin, lead, silver, cobalt, manganese and copper are suitable and used for this purpose.

After the activation, either a current-free metallization of the surface as a conductive layer is carried out, followed the electrolytic layer formation, or a galvanic metal separation is directly carried out.

Mixed polymers of acrylonitrile-butadiene-styrene (ABS) are particularly well suited for galvanizing because of their rubber phase, and in addition to ABS polycarbonate mixtures, they are the predominant metallized polymers. Other plastics, such as polyacetal, polysulfone, polycarbonate, polystyrene, polyamide, polypropylene or polyphenyl oxide can either not be metallized at all with the known methods or only at increased expenditure, and thus at high cost. The known method presents the drawback that higher doped ABS-PC blends (more than 45% PC component) as well as other plastic types can only be galvanized at increased cost, if at all. In such a process, to obtain a relatively satisfactory metal layer, several process steps, often multiple activation steps, are carried out repeatedly in succession. This approach is not only time-consuming, it also leads to a disadvantageous increase in the costs. Although with some methods it is possible to metallize the plastic surfaces by using an etching agent which is matched to a given type of plastic to be metallized and by other expensive adaptations of the process, the results are not sufficiently reproducible and the adhesion is not satisfactory. Therefore, the direct metallization of many plastic surfaces has been possible only to a limited extent to date.

The known methods are, moreover, frequently exceedingly susceptible to defects and very precise working conditions are required to guarantee that an optimal preparation of the plastic surface and a reliable adhesion of the metal layer to the plastic surface. Therefore, exceedingly precise controls are required to keep the defect rates low. In particular, excessively long etching times roughen the surface too much and change it disadvantageously.

### SUMMARY OF THE INVENTION

Among the several objects of the present invention, therefore, may be noted the provision of a method for the metallization of a plastic surface which cannot be metallized by means of conventional etching and activation steps and the provision of a method for the metallization of a plastic surface by means of a single activation step. Other objects and features will be in part apparent and in part pointed out hereinafter.

Briefly therefore, the present invention is directed to a method for metallizing a plastic surface, which comprises the step of preactivating the plastic surface. The surface is preactivated by contacting the plastic surface with a solution comprising permanganate, a crosslinking agent, and a pH buffer material. The present invention is further directed to a solution for preparing a plastic surface for metallization. The solution comprising permanganate, a crosslinking agent, and a pH buffer material.

### DETAILED DESCRIPTION OF THE PREFERRED EMBODIMENTS

As a result of the method according to the invention, an additional treatment step is introduced, which is carried out after the etching or neutralization of the plastic surface, but before the activation proper by, for example, palladium activators or metal complex activators. In this process, the plastic surface to be metallized is immersed in a solution which comprises an oxidizer such as permanganate and a crosslinking agent. Preferably, the solution concentrations of these components are from about 0.1 to about 100 g/L permanganate and from about 0.001 to about 10 g/L of the crosslinking agent. The solution effects a preactivation of the plastic surface, so that after this preactivation treatment, the activation can be carried out more effectively. As a result of the use of the crosslinking agent, a good wetting of the metallizing surface is achieved.

It has been found that the preactivation step is pH dependent, and preferably the solution is slightly acidic, since the effectiveness of the preactivation increases with decreasing pH, while at the same time there is a tendency for the permanganate to self-decompose with decreasing pH. This is particularly so if potassium permanganate is used, in which case a pH of about 2 represents a lower limit. Preferably, the pH range of the preactivation solution is from about 4 to about 7. Thus, the preactivation solution preferably comprises a pH buffer material for the pH range of from about 2 to about 12. Preferably, the buffer is present in a concentration of from about 1 to about 100 g/L. As a result, it is guaranteed that the pH of the solution remains substantially constant and thus it optimally prepares the plastic surface. Without the use of a buffer system, the reaction of the permanganate with the molecules of the plastic surface would lead to a rapid change in the pH, which in turn would lead to a reduction in the efficiency.

The preactivation treatment according to the invention advantageously leads to the plastic surface being chemically modified by the reactions of the permanganate with the polymer molecules of the plastic surface, so that a clear improvement of the ability of plastic surfaces to galvanize is effected, or in the case of some plastics, a surface becomes capable of being coated at all. Thus, as a result of the method according to the invention, it is possible to omit the multiple activation which was required in the past, and thus the method according to the invention becomes exceedingly economic compared to the known methods. The method according to the invention is furthermore characterized in that the plastic surface to be metallized is less subject to defects and can be metallized at lower costs. Thus, it is not necessary to proceed to extensive adaptations of the etching agents and other solutions to a given plastic to be metallized, because, as a result of the preactivation, plastics of a great variety become reliably metallizable. The preactivation solution is also less aggressive, so that a longer work period can be used, because fixed immersion times, temperatures, etc., do not have to be maintained at great costs, and as a result, the method according to the invention is considerably more stable. As a result, the method according to the invention presents a good reproducibility and low defect rates. Furthermore, in carrying out the method, it is possible to reliably prevent coating of supports. As a result of this process, the plastic surface, after the etching or the neutralization, is chemically modified and thus preactivated. In connection with the etching, the preactivation leads to an improvement of the ability of the plastics to be galvanized, or in some cases it makes galvanization possible. With the method according to the invention, the galvanization conditions do not have to be adapted in each case to the plastic to be metallized to achieve a reliable metallization, provided it is possible at all, rather, a great variety of plastics, listed as examples in the introduction, can be metallized by the method according to the invention without expensive process adaptations. As a result of the combination of etching and preactivation by means of the described solution, the plastic surface is optimally prepared, so that the activation step has to be carried out only once to be able to apply a reliably adhering metal layer. In its application, different etching agents and activation methods can be used in the method according to the invention because it has been shown that the preactivation treatment of the plastic surface in the preactivation solution is the primary determining factor in the success of the method according to the invention.

The treatment of the plastic surface to be metallized is carried out with a solution whose temperature is from about 0 to about 70° C, preferably from about 30 to about 50° C. As a result, it is possible to work in a large temperature range, and temperature is not as critical a parameter. In the process, the temperature can be selected and adjusted after other conditions are fixed, such as the concentration of the oxidizing agent. As a result, it also becomes advantageously possible to carry out the work at lower temperatures, resulting in the possibility of saving energy and thus costs. The process may be carried out in a time of from about 1 to about 15 minutes, preferably from about 4 to about 6 minutes. It is preferred to move the solution and/or the plastic part to be metallized in the solution. A movement of the bath can be achieved, for example, by blowing air into it. The resulting flow of the solution across the surface of the plastic part is advantageous, enabling the solution to act optimally on the plastic surface to be preactivated. As a result, a reliable and qualitatively good adhesion is possible, even without double activation.

Preferably, the solution for the preactivation treatment which contains potassium permanganate as oxidizing agent. The use of potassium permanganate has here been shown to be advantageous in chemically modifying the plastic surface, greatly increasing the proportion of C—O bonds on the hydrophilic surface groups. Mixtures, consisting of permanganate and one or more compounds of elements of the 4^{th} to 6^{th} main and subgroups are useful, with the oxygen compounds of the 4^{th} to 6^{th} main and subgroups having been shown to be particularly effective. It is preferred to use a solution which contains 5-10 g/L potassium permanganate.

For wetting the plastic surface to be metallized the solution for the preactivation treatment of the plastic surface preferably comprises from about 0.01 to about 0.1 g/L of a perfluorinated and/or partially perfluorinated crosslinking agent. The use of such oxidation-resistant crosslinking agents is advantageous because, in that manner, possible oxidations by the permanganate are prevented.

Since it has been shown that the advantageous effect of the solution presents pH dependence, it is preferable to add to the solution a pH buffer material which works in a pH range of 2-12. Useful buffer salts include sodium tetraborate or potassium dihydrogen phosphate at a concentrations of from about 5 to about 15 g/L.

### EXAMPLE 1

PA and PC Plastics

The plastic surface to be metallized is treated with a conventional chromosulfuric acid etching solution, so that the plastic surface is roughened. The etching process is followed by the associated rinsing steps. Optionally, a neutralization step with associated rinsing steps can be used subsequently.

After the etching or the neutralization and the associated rinsing steps, the plastic part to be metallized is immersed in a solution in order to preactivate the surface prior to the activation step. For this purpose, the work part is immersed in a solution, which contains 5-10 g/L KMnO₄, 0.01-0.1 g/L of a perfluorinated or partially fluorinated crosslinking agent, as well as 5-15 g/L sodium tetraborate. The temperature of the solution is 30-50° C. The work part is rinsed by the solution, either by moving the bath and/or by moving the work part. The plastic part to be metallized is immersed for 4-6 minutes in the solution; however, longer immersion times (up to 10-15 minutes) can be used without causing damage and do not lead to any disadvantageous effect on the plastic surface.

After the preactivation with the above-described solution, and the compulsory rinsing steps, activation is carried out. This can occur using the activation methods which are known in the state of the art and indicated here only as examples. Thus, the pretreated surface which has been chemically modified by the solution can be activated with rare-metal activators or with the metal complexes described elsewhere herein. For example, the work part to be metallized is immersed for a time period of 10 minutes in an ammonia solution which contains 0.1 mol/L CoSO₄ and has a pH of 10 and a temperature of approximately 20° C. Subsequently, the plastic parts to be metallized are treated with water, whose pH has been adjusted to 13, using a base such as NaOH. Then, a treatment with a sulfide solution containing 0.01M Na₂iS₂ is carried out. After this treatment, the objects are rinsed with distilled water, dried, and then nickel plated electrochemically in a Watt-type electrolyte.

Without the preactivation, the steps, starting with the activation in the ammonia solution, would have to be repeated one to two times, to make it possible at all to nickel plate these plastic types in a Watt-type nickel electrolyte.

### EXAMPLE 2

ABS/PC Blends (85% PC Proportion)

The plastic surface to be metallized is treated with a conventional chromosulfuric acid etching solution, so that the plastic surface is roughened. The etching process is followed by the associated rinsing steps. Moreover, a neutralization step with the associated rinsing steps can optionally be carried out subsequently.

After the etching or the neutralization and the associated rinsing steps, the plastic part to be metallized is immersed in a solution in order to preactivate the surface prior to the activation step. For this purpose, the work part is immersed in a solution which contains 5-10 g/L KMnO₄, 0.01-0.1 g/L of a perfluorinated or partially fluorinated crosslinking agent, as well as 5-15 g/L potassium dihydrogen phosphate. The temperature of the solution is 30-50° C. The work part is rinsed by the solution, either by moving the bath and/or by moving the work part. The plastic part to be metallized is immersed for 4-6 minutes in a solution, but longer immersion time (up to 10-15 minutes) do not cause damage and do not lead to a disadvantageous damaging of the plastic surface.

After the preactivation with the above-described solution as well as the compulsory rinsing steps, activation is carried out. This can be carried out by the activation methods known in the state of the art, and mentioned here only as examples. Thus the surface which has been pretreated and chemically modified by the solution can be activated with rare-metal activators or with the metal complexes mentioned elsewhere herein. For example, the work part to be metallized is immersed for a time period of 5 minutes in a Pd/Sn colloid-containing solution which contains 200-250 gm/L palladium, 10 g/L tin(II) and 110 g/L HCl, and which has a temperature of approximately 40° C. Subsequently, the plastic parts to be metallized are rinsed and immersed for approximately 4 minutes in a solution which, in each case, contains 10 g/L thiosulfuric compound and a hydrocarboxylic acid, and which has a temperature of approximately 55° C. Subsequently, the work parts to be metallized are rinsed and copper plated in a sulfuric acid-containing copper electrolyte.

Without the preactivation according to the invention, ABS/PC blends with a PC component of approximately 85% cannot be galvanized at all, or only work parts having an extremely small surface can be galvanized analogously to this example. Therefore, with preactivation, it is also possible to reliably galvanize ABS-PC work parts (85% PC component) having large surface areas.

### Example 3

Polypropylene (PP)

The plastic surface to be metallized is treated with a conventional chromosulfuric acid-containing etching solution, so that the plastic surface is roughened. The etching process is followed by the associated rinsing steps. Subsequently, a neutralization step with the associated rinsing step may follow.

After the etching or the neutralization and the associated rinsing steps, the plastic part to be metallized is immersed in a solution in order to preactivate the surface prior to the activation step. For this purpose, the work part is immersed in a solution which contains 5-10 g/L KMnO₄, 0.01-0.1 g/L of a perfluorinated or partially fluorinated crosslinking agent, as well as 5-15 g/L sodium citrate and 2-6 g/L citric acid. The temperature of the solution is 30-50° C. The work part is washed by the solution, by the movement of the bath and/or the movement of the work part. The plastic part to be metallized is immersed for 4-6 minutes in the solution, but longer immersion times (up to 10-15 minutes) also do not cause damage and do not lead to a disadvantageous damaging of the plastic surface.

After the preactivation with the above-described solution as well as the compulsory rinsing steps, activation is carried out. The activation can be carried out using the activation methods known in the state of the art. Thus, the surface which has been pretreated, and chemically modified by the solution, can be activated with rare-metal activators or with the metal complexes described elsewhere herein. For example, the plastic parts to be metallized are immersed for a time period of approximately 5 minutes in a Sn/Pd colloid-containing solution which contains 60-80 mg/L palladium, 10 g/L tin(II) as well as 110 g/L HCl, and which has a temperature of approximately 30° C. Subsequently, the metal parts to be metallized are rinsed and treated for approximately 2 minutes in a solution consisting of 70 g/L of a dicarboxylic acid, at a temperature of approximately 50° C. Subsequently, the work parts to be metallized are rinsed, and they are subjected to a preliminary nickel plating in ammonia-containing, or ammonia-free, electroless, nickel electrolyte for approximately 7 minutes at a temperature of approximately 30° C., before the subsequent galvanic layer formation is carried out.

It was shown that if preactivation according to the invention and its embodiments is used, the electroless separation of nickel occurs more regularly, and the nickel plating which is separated in this manner presents higher specific conductivities in comparison to nickel platings which were prepared analogously but without preactivation.

In view of the above, it will be seen that the several objects of the invention are achieved and other advantageous results attained. When introducing elements of the present invention or the preferred embodiment(s) thereof, the articles “a”, “an”, “the” and “said” are intended to mean that there are one or more of the elements. The terms “comprising”, “including” and “having” are intended to be inclusive and mean that there may be additional elements other than the listed elements. As various changes could be made in the above products and methods without departing from the scope of the invention, it is intended that all matter contained in the above description shall be interpreted as illustrative and not in a limiting sense.

What is claimed is:

1. A method for metallizing a plastic surface, the method comprising preactivating the plastic surface by contacting the plastic surface with a solution comprising permanganate, a crosslinking agent, and a pH buffer material.

2. The method according to claim 1 wherein the solution has a permanganate concentration of from about 0.1 g/L to about 100 g/L.

3. The method according to claim 1 wherein the permanganate comprises potassium permanganate.

4. The method according to claim 3 wherein the solution has a potassium permanganate concentration of from about 5 g/L to about 10 g/L.

5. The method according to claim 1 wherein the solution has a crosslinking agent concentration of from about 0.001 g/L to about 10 g/L.

6. The method according to claim 1 wherein the crosslinking agent comprises a fluorinated crosslinker selected from the group consisting of a perfluorinated crosslinking agent and a partially perfluorinated crosslinking agent.

7. The method according to claim 6 wherein the solution has a fluorinated crosslinker concentration of from about 0.01 g/L to about 0.1 g/L.

8. The method according to claim 1 wherein the solution is buffered in a pH range from about 2 to about 12.

9. The method according to claim 1 wherein the solution is buffered in a pH range from about 4 to about 7.

10. The method according to claim 1 wherein the solution has a pH buffer material concentration of from about 1 g/L to about 100 g/L.

11. The method according to claim 1 wherein the pH buffer material comprises a buffer salt selected from the group consisting of sodium tetraborate and potassium dihydrogen phosphate.

12. The method according to claim 11 wherein the solution has a buffer salt concentration of from about 5 g/L to about 15 g/L.

13. The method according to claim 1 wherein the solution the solution has a temperature of from about 0° C. to about 70° C.

14. The method according to claim 1 wherein the solution the solution has a temperature of from about 30° C. to about 50° C.

15. The method according to claim 1 wherein the plastic surface is contacted with the solution for a duration of from about 1 minute to about 15 minutes.

16. The method according to claim 1 wherein the plastic surface is contacted with the solution for a duration of from about 4 minute to about 6 minutes.

17. The method according to claim 1 wherein contacting the plastic surface with the solution is characterized by establishing a flow of the solution across the plastic surface.

18. The method according to claim 1 further comprising the steps of:
etching the plastic surface prior to the preactivation step;
activating the plastic surface following the preactivation step; and
metallizing the activated plastic surface.

19. The method according to claim 1 wherein the plastic surface comprises a compound selected from the group consisting of acrylonitrile-butadiene-styrene (ABS), an ABS polycarbonate mixtures, polyacetal, polysulfone, polycarbonate, polystyrene, polyamide, polypropylene, and polyphenyl oxide.

20. A method for metallizing a plastic surface, the method comprising:
preactivating the plastic surface by contacting the plastic surface for a duration of from about 1 to about 15 minutes with a solution comprising:
from about 5 g/L to about 10 g/L potassium permanganate;
from about 0.01 g/L to about 0.1 g/L of a fluorinated crosslinking agent; and
from about 5 g/L to about 15 g/L of a salt buffer selected from the group consisting of sodium tetraborate and potassium dihydrogen phosphate;
wherein the solution has a temperature of from about 30° C. to about 50° C. and a pH from about 4 to about 7.

21. A solution for preparing a plastic surface for metallization comprising permanganate, a crosslinking agent, and a pH buffer material.

22. The solution according to claim 21 wherein the solution has a permanganate concentration of from about 0.1 g/L to about 100 g/L.

23. The solution according to claim 21 wherein the permanganate comprises potassium permanganate.

24. The solution according to claim 23 wherein the solution has a potassium permanganate concentration of from about 5 g/L to about 10 g/L.

25. The solution according to claim 21 wherein the solution has a crosslinking agent concentration of from about 0.001 g/L to about 10 g/L.

26. The solution according to claim 21 wherein the crosslinking agent comprises a fluorinated crosslinker selected from the group consisting of a perfluorinated crosslinking agent and a partially perfluorinated crosslinking agent.

27. The solution according to claim 26 wherein the solution has a fluorinated crosslinker concentration of from about 0.01 g/L to about 0.1 g/L.

28. The solution according to claim 21 wherein the solution is buffered in a pH range from about 2 to about 12.

29. The solution according to claim 21 wherein the solution is buffered in a pH range from about 4 to about 7.

30. The solution according to claim 21 wherein the solution has a pH buffer material concentration of from about 1 g/L to about 100 g/L.

31. The solution according to claim 21 wherein the pH buffer material comprises a buffer salt selected from the group consisting of sodium tetraborate and potassium dihydrogen phosphate.

32. The solution according to claim 30 wherein the solution has a buffer salt concentration of from about 5 g/L to about 15 g/L.

33. A solution for preparing a plastic surface for metallization comprising:
from about 5 g/L to about 10 g/L potassium permanganate;
from about 0.01 g/L to about 0.1 g/L of a fluoronated crosslinking agent; and
from about 5 g/L to about 15 g/L of a salt buffer selected from the group consisting of sodium tetraborate and potassium dihydrogen phosphate.
